(19) United States
(12) Patent Application Publication
(10) Pub. No.: US 2019/0235006 A1
(43) Pub. Date: Aug. 1, 2019

(54) WIRING LINE ABNORMALITY DETECTING DEVICE

(71) Applicant: DENSO CORPORATION, Kairiya-city (JP)

(72) Inventor: Satoshi ICHIKAWA, Kariya-city (JP)

(21) Appl. No.: 16/378,615

(22) Filed: Apr. 9, 2019

Related U.S. Application Data
(63) Continuation of application No. PCT/JP2017/036989, filed on Oct. 12, 2017.

(30) Foreign Application Priority Data
Nov. 21, 2016 (JP) 2016-225939

(51) Int. Cl. G01R 31/02; G01N 27/409; G01N 27/419; F01N 3/08; F02D 41/24

(52) U.S. Cl. CPC G01R 31/024; G01N 27/409; F01N 2560/026; F01N 3/08; F02D 41/2474; G01N 27/419

(57) ABSTRACT

A wiring line abnormality detecting device is configured to be provided in a sensor signal detection device that includes a detection unit for detecting a sensor signal through a plurality of wiring lines connected to a sensor, and includes a potential detection unit that detects each of potentials of the plurality of wiring lines, a potential difference detection circuit that detects a potential difference between the plurality of wiring lines according to each of the potentials of the plurality of wiring lines detected by the potential detection unit, and a determination circuit that specifies a failure wiring line with a high-voltage power supply short circuit among the plurality of wiring lines according to the potential difference detected by the potential difference detection unit.

### CROSS REFERENCE TO RELATED APPLICATIONS

The present application is a continuation application of International Patent Application No. PCT/JP2017/036989 filed on Oct. 12, 2017, which designated the U.S. and claims the benefit of priority from Japanese Patent Application No. 2016-225939 filed on Nov. 21, 2016. The entire disclosures of all of the above applications are incorporated herein by reference.

### TECHNICAL FIELD

The present disclosure relates to a wiring line abnormality detecting device.

### BACKGROUND

As a sensor signal detection device, there is a sensor using a resistive element such as a gas concentration sensor.

### SUMMARY

The present disclosure provides a wiring line abnormality detecting device that is configured to be provided in a sensor signal detection device including a detection unit for detecting a sensor signal through multiple wiring lines connected to a sensor, detects each of potentials of the multiple wiring lines, detects a potential difference between the multiple wiring lines according to each of the potentials of the multiple wiring lines, and specifies a failure wiring line with a high-voltage power supply short circuit among the multiple wiring lines according to the potential difference.

### BRIEF DESCRIPTION OF DRAWINGS

The above and other objects, features and advantages of the present disclosure will become more apparent from the following detailed description made with reference to the accompanying drawings. In the drawings:

FIG. 1 is an electric configuration diagram showing a first embodiment;

FIG. 2 is an electric configuration diagram of an overvoltage detection circuit;

FIG. 3 is a time chart showing changes in voltages and signals in a case where a wiring line L1 is short-circuited to a high-voltage power supply;

FIG. 4 is a time chart showing changes in voltages and signals in a case where a wiring line L2 is short-circuited to the high-voltage power supply;

FIG. 5 is a time chart showing changes in voltages and signals in a case where both the wiring line L1 and the wiring line L2 are short-circuited to the high-voltage power supply;

FIG. 6 is a diagram showing a correspondence between an output signal state and a short circuit state;

FIG. 7 is an electric configuration diagram of an overvoltage detection circuit according to a second embodiment;

FIG. 8 is an electric configuration diagram showing a third embodiment;

FIG. 9 is an electric configuration diagram showing a fourth embodiment;

FIG. 10 is an electric configuration diagram showing a fifth embodiment; and

FIG. 11 is an electric configuration diagram showing a sixth embodiment.

### DETAILED DESCRIPTION

Although some gas concentration sensors detect an abnormality in wiring lines, impedance of the gas concentration sensors may become low after been activated. For that reason, when any of wiring lines connected to two terminals is short-circuited to a high-voltage power supply line, both of the two terminals become high voltages and exceed a threshold for abnormality detection. Thus, even though an abnormal state can be detected, an abnormal portion cannot be specified.

A wiring line abnormality detecting device according to an aspect of the present disclosure is configured to be provided in a sensor signal detection device that includes a detection unit for detecting a sensor signal through multiple wiring lines connected to a sensor, and includes a potential detection unit that detects each of potentials of the multiple wiring lines, a potential difference detection circuit that detects a potential difference between the multiple wiring lines according to each of the potentials of the multiple wiring lines detected by the potential detection unit, and a determination circuit that specifies a failure wiring line with a high-voltage power supply short circuit among the multiple wiring lines according to the potential difference detected by the potential difference detection unit.

In the above configuration, when a high-voltage power supply short circuit has occurred in one of the multiple wiring lines connected between the sensor and the sensor signal detection device, an impedance of the sensor is low and voltages of all of the wiring lines rise to a high voltage. Thus, by determination of a voltage level of each of the wiring lines, even though it can be determined that all of the wiring lines become the high voltage level and the high-voltage power supply short circuit has occurred, it cannot be specified in which wiring line the high-voltage power supply short circuit has occurred.

On the other hand, the potential difference detection circuit detects the potential difference between the wiring lines from the potentials detected by the potential detection unit, and the determination circuit can specify in which wiring line the high-voltage power supply short circuit has occurred by determining that the value of the detected potential difference is a value that has changed by a predetermined level or more, which is positive or negative.

Further, as described above, in a state where it can be determined that the high-voltage power supply short circuit has occurred, when the potential difference detected by the potential difference detection circuit is small and cannot be obtained as a value equal to or higher than a predetermined level of positive or negative, it is expected that all of the wiring lines have voltages close to the high-voltage power supply. In that case, it can be determined by the determination circuit that the high-voltage power supply short circuit has occurred in all terminals.

### First Embodiment

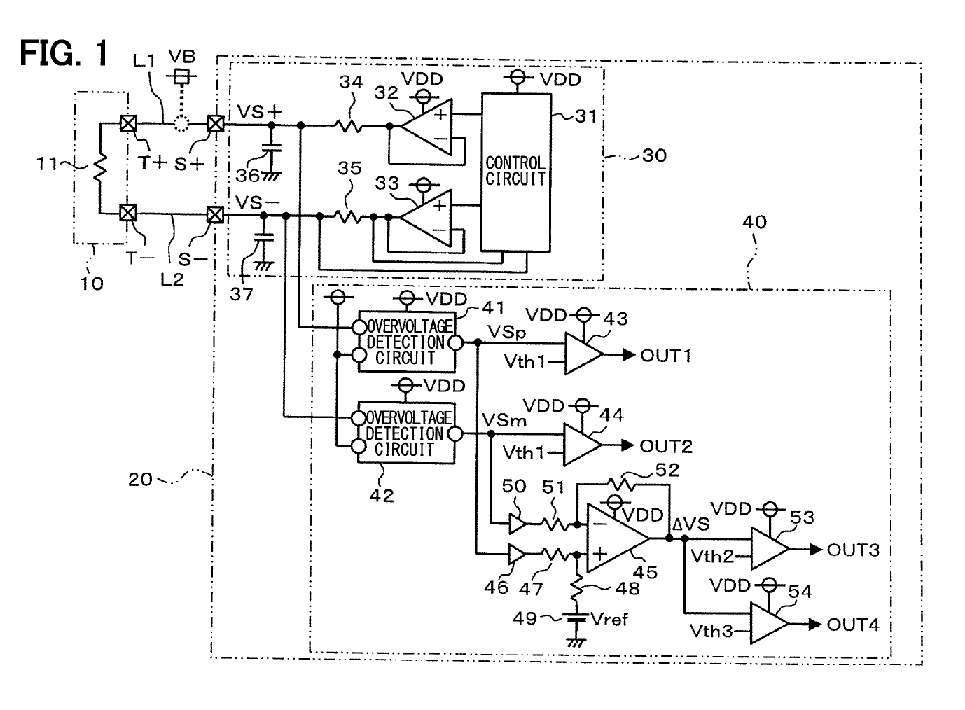

Hereinafter, a first embodiment will be described with reference to FIGS. 1 to 6. In the present embodiment, for example, a gas concentration sensor 10 is used as a sensor. The gas concentration sensor 10 detects, for example, an oxygen concentration of an exhaust gas of an engine of a vehicle, and both terminals T+ and T− of a resistive portion 11 are connected to terminals S+ and S− of a gas concentration detection device 20 through wiring lines L1 and L2, respectively. The sensor 10 is heated by a heater circuit (not shown) at the time of measuring the oxygen concentration.

The gas concentration detection device 20 includes a gas concentration detection unit 30 corresponding to a sensor signal detection device and a wiring line abnormality detection unit 40 corresponding to a wiring line abnormality detecting device. A predetermined DC power supply VDD is supplied from a power supply circuit (not shown) to the gas concentration detection device 20.

The gas concentration detection unit 30 is mainly configured by a control circuit 31, and includes two amplifiers 32 and 33, resistors 34 and 35, and capacitors 36 and 37. The control circuit 31 gives an output for detection from the amplifiers 32 and 33 to the terminals S+ and S− through the resistors 34 and 35, respectively. The sensor 10 is biased by a voltage applied through the wiring lines L1 and L2, and a detection signal corresponding to the gas concentration is obtained by detecting a voltage that appears between the terminals of the resistor 35. In addition, the sensor 10 has a low resistance in a high temperature state at the time of measurement as compared with a resistance value in a normal temperature state. The capacitors 36 and 37 have a function of absorbing noise, and configure a filter together with the resistors 34 and 35.

Next, in the wiring line abnormality detection unit 40, two overvoltage detection circuits 41 and 42 as a potential detection unit and a level shift circuit are provided so as to detect voltages of the terminals S+ and S− to which the wiring lines L1 and L2 are connected, respectively. The overvoltage detection circuits 41 and 42 are driven by a power supply voltage VDD, and upon receiving a voltage greater than or equal to the power supply voltage VDD, the overvoltage detection circuits 41 and 42 convert the received voltage into a current, further convert the converted current into a voltage signal based on the power supply voltage VDD, and output the converted voltage signal.

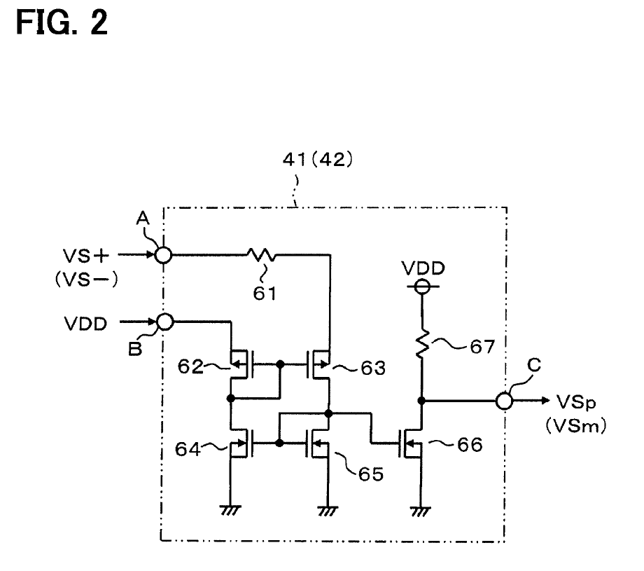

Specifically, the overvoltage detection circuits 41 and 42 are configured as shown in FIG. 2. Since configurations of both overvoltage detection circuits 41 and 42 are the same, the overvoltage detection circuit 41 will be described. The overvoltage detection circuit 41 includes input terminals A and B and an output terminal C. The input terminal A is connected to the terminal S+ (S−), and the input terminal B is supplied with the power supply voltage VDD.

In the overvoltage detection circuit 41, an input stage includes a current conversion unit having a resistor 61, p-channel MOSFETs 62, 63 and n-channel MOSFETs 64, 65, and a voltage conversion unit having an n-channel MOSFET 66 and a resistor 67. The input terminal A is connected to the ground through the resistor 61, the MOSFET 63, and the resistor 65. The input terminal B is connected to the ground through the MOSFET 62 and the input terminal 64. Both the MOSFET 62 and the MOSFET 65 are short-circuited between drains and gates.

The MOSFETs 62 and 63 and the MOSFETs 64 and 65 configure current mirror circuits. A source of the MOSFET 66 is grounded, a drain of the MOSFET 66 is connected to the DC power supply VDD through the resistor 67, and a gate of the MOSFET 66 is connected to a drain of the MOSFET 63. The drain of the MOSFET 66 is connected to the output terminal C.

When a voltage VS+ of the terminal S+ input to the input terminal A exceeds the power supply voltage VDD, the overvoltage detection circuit 41 operates by being applied with a voltage exceeding a threshold voltage to the MOSFET 63, and a current also flows through the other MOSFETs 62, 64, and 65. At that time, a source of the MOSFET 63 is clamped to the power supply voltage VDD, a differential voltage ΔV (=(VS+)−VDD) between the terminal voltage VS+ and the power supply voltage VDD is applied to the resistor 61, and a current Id flowing through the resistor 61 becomes a value (Id=ΔV/R) obtained by dividing the differential voltage ΔV by a resistance value R of the resistor 61.

In other words, the differential voltage ΔV corresponding to the amount of the terminal voltage VS+ exceeding the power supply voltage VDD is converted into the current Id. Since the MOSFETs 65 and 66 configure a current mirror circuit, the current Id also flows in the MOSFET 66 circuit, and a voltage corresponding to the differential voltage ΔV is generated in the resistor 67 as a voltage of a level converted by the power supply voltage VDD. As a result, an output voltage VSp (VSm) obtained by converting a level of the terminal voltage VS+(VS−) to the detection level with reference to the power supply voltage VDD can be output to the output terminal C.

The comparators 43 and 44 compare the output voltages VSp and VSm of the overvoltage detection circuits 41 and 42 with a threshold voltage Vth1, respectively, and output the result as output signals OUT1 and OUT2. The threshold voltage Vth1 is set so that levels of the voltages VS+ and VS− are set to a predetermined level equal to or higher than the power supply voltage VDD, and when a high voltage exceeding the power supply voltage VDD is applied to the wiring line L1 or L2, this fact is detected.

A differential amplifier 45 as a potential difference detection circuit calculates a difference between the output voltages VSp and VSm of the overvoltage detection circuits 41 and 42 and outputs the differential voltage ΔVS. A non-inverting input terminal of the differential amplifier 45 receives the output voltage VSp from the output terminal C of the overvoltage detection circuit 41 through a buffer circuit 46 and the resistor 47. The non-inverting input terminal of the differential amplifier 45 is connected to the ground through a resistor 48 and a reference power supply 49. The reference power supply 49 is set with a voltage of ½ of the power supply voltage VDD as a reference voltage Vref. The output voltage VSm is input to an inverting input terminal of the differential amplifier 45 from the output terminal C of the overvoltage detection circuit 42 through the buffer circuit 50 and the resistor 51. A resistor 52 is connected between the inverting input terminal of the differential amplifier 45 and the output terminal.

In the overvoltage detection circuits 41 and 42, when the voltages VS+ and VS− of the terminals S+ and S− do not reach the power supply voltage VDD, the output voltages VSp and VSm are zero. Therefore, in that condition, the differential amplifier 45 outputs the voltage Vref input to the non-inverting input terminal, that is, a voltage of ½ of the power supply voltage VDD as the differential voltage ΔVS.

Further, when the voltages VS+ and VS− of the terminals S+ and S− exceed the power supply voltage VDD, the output voltage VSp or VSm on any one of the overvoltage detection circuits 41 and 42, which exceeds the power supply voltage VDD, is output as a voltage corresponding to the amount exceeding the power supply voltage VDD, so that the voltage is output in a state where the amount is added to the differential voltage ΔVS.

Comparators 53 and 54 as the determination circuits are provided so as to receive the differential voltage ΔVS, which is the output of the differential amplifier 45. In the comparators 53 and 54, the voltages to be compared are set to threshold voltages Vth2 and Vth3, respectively. The threshold voltages Vth2 and Vth3 are to set determination levels for detecting a case where the wiring line L1 or L2 connected to the terminal S+ or S− is short-circuited with a power supply line having a voltage higher than the power supply voltage VDD. The comparators 53 and 54 compare the differential voltage ΔVS with the threshold voltage Vth2 or Vth3, and output the results as output signals OUT3 and OUT4.

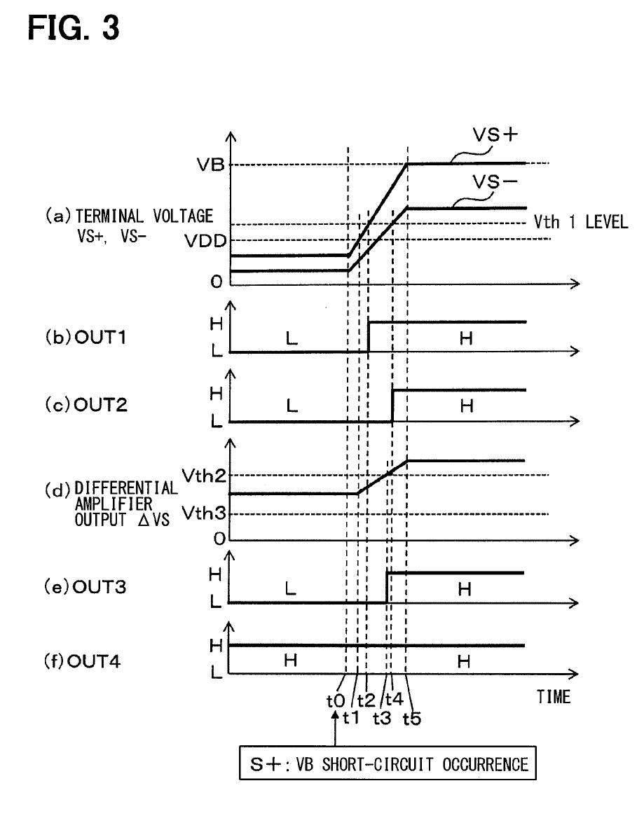

Next, the operation of the above configuration will be described with reference to FIGS. 3 to 6. The detection operation of the gas concentration by the gas concentration sensor 10 and the gas concentration detection unit 30 is performed by detecting a voltage appearing in the resistor 35 in a state where a heater (not shown) is energized and the gas concentration sensor 10 is heated by the control circuit 31. Since the operation is a well-known technique, a detailed description of the operation will be omitted.

In the present embodiment, the operation of detecting a state where a fault occurs in one or both of the wiring line L1 and the wiring line L2 by the abnormality detection unit 40 in a state where the gas concentration is detected by the gas concentration detection unit 30 will be described below. In this case, in the present embodiment, in particular, a state where a power supply line such as a power supply VB having a voltage higher than the power supply voltage VDD (hereinafter referred to as a high-voltage power supply VB) comes in electric contact with the wiring lines L1 and L2 to cause an abnormality state is detected.

There are three cases of the abnormal state including (1) a case where the wiring line L1 is short-circuited to VB; (2) a case where the wiring line L2 is short-circuited to VB; and (3) a case where both the wiring lines L1 and L2 are short-circuited to VB. Hereinafter, those three cases will be described.

### (1) Case Where the Wiring L1 is Short-Circuited to VB

This state is a state where the high-voltage power supply VB is short-circuited to the wiring line L1, as shown in FIG. 1. FIG. 3 shows a transition of a change in a signal of each part corresponding to that case. It is assumed that the wiring line L1 is short-circuited to the high-voltage power supply VB at a time t0.

First, when a state before the time t0, that is, when the normal operation in which the short circuit does not occur is performed, a predetermined voltage is applied in a state where the gas concentration sensor 10 is heated by the detection operation of the gas concentration detection unit 30, and the detection operation of the gas concentration is performed by the current. In this state, potentials are generated at the terminals T+ and T− of the gas concentration sensor 10 in the wiring lines L1 and L2, respectively, and the voltages appear at the terminals S+ and S−. At that time, since the gas concentration sensor 10 is in a low impedance state, although the respective potentials are low, a potential difference is generated between the terminals T+ and T−. The terminal voltages VS+ and VS− are equal to or lower than the power supply voltage VDD and become voltages of a predetermined level.

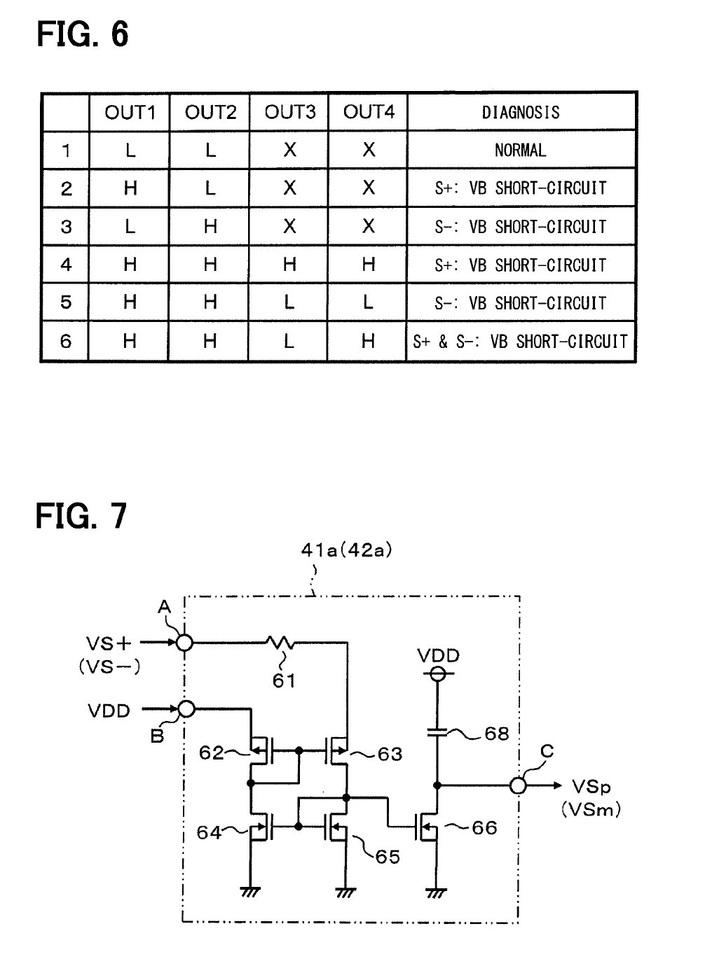

In that state, the output voltages VSp and VSm of the overvoltage detection circuits 41 and 42 are both zero. Therefore, since both of the comparators 43 and 44 are smaller than a level set by the threshold voltage Vth1, the output signals OUT1 and OUT2 are at the low level. As a result, at a level of the normal state, as indicated by “1” in FIG. 6, OUT1 and OUT2 become “L” and are recognized as the “normal” state.

At that time, since both of the output voltages VSp and VSm are zero, the reference voltage Vref is output as it is, as the output signal ΔVS of the differential amplifier 45. Since a level of the reference voltage Vref is set to half of the power supply voltage VDD, the reference voltage is lower than the threshold voltage Vth2 and higher than the threshold voltage Vth3.

When the wiring line L1 is short-circuited to the high-voltage power supply VB at the time t0 from the normal state described above, the terminal voltages VS+ and VS− rise together as shown in (a) in FIG. 3, the terminal voltage VS+ reaches the level of the high-voltage power supply VB, and the terminal voltage VS− reaches the level lower than the high-voltage power supply VB. When the terminal voltage VS+ rises and exceeds the power supply voltage VDD at a time t1, a voltage corresponding to a difference between the terminal voltage VS+ and the power supply voltage VDD is output as the output voltage VSp of the overvoltage detection circuit 41. Similarly, when the terminal voltage VS− exceeds the power supply voltage VDD, a voltage corresponding to a difference between the terminal voltage VS− and the power supply voltage VDD is output as the output voltage VSm of the overvoltage detection circuit 42.

When the terminal voltage VS+ rises and reaches the threshold voltage Vth1 level at a time t2, the output voltage VSp of the overvoltage detection circuit 41 becomes equal to the threshold voltage Vth1 in the comparator 43, and the output signal OUT1 changes from a low level to a high level as shown in (b) in FIG. 3. At that time point, it can be seen that the wiring line L1 connected to the terminal S+ is in contact with the high-voltage power supply VB, and thus has a high voltage. Therefore, a state indicated by “2” in FIG. 6 is obtained.

However, immediately after the above situation, when the terminal voltage VS− rises and reaches the threshold voltage Vth1 level at a time t4, the output voltage VSm of the overvoltage detection circuit 42 becomes equal to the threshold voltage Vth1 in the comparator 44, and the output signal OUT2 changes from the low level to the high level as shown in (c) in FIG. 3. As a result, since both of the output signals OUT1 and OUT2 become high level, a state where one or both of the terminals S+ and S− are short-circuited to a high voltage exceeding the power supply voltage VDD can be determined, but it cannot be specified which terminal is short-circuited.

On the other hand, the differential amplifier 45 outputs the result of calculating the differential voltage between the output voltages VSp and VSm of the overvoltage detection circuits 41 and 42 as the differential voltage ΔVS as shown in (d) in FIG. 3. When the differential voltage ΔVS rises to a positive side and exceeds the threshold voltage Vth2, the comparator 53 outputs the output signal OUT3 of the high level at the time t3, as shown in (e) in FIG. 3. Since the level of the differential voltage ΔVS before the time t0 has already exceeded the threshold voltage Vth3, the comparator 54 continues to output the high level output signal OUT4 even after the time t3. As a result, as a state indicated by “4” in FIG. 6, all of the output signals OUT1 to OUT4 are obtained as the “H” state, and the S+ terminal can be recognized as a state which is short-circuited to the high-voltage power supply VB.

### (2) Case in Which the Wiring Line L2 is Short-Circuited to VB

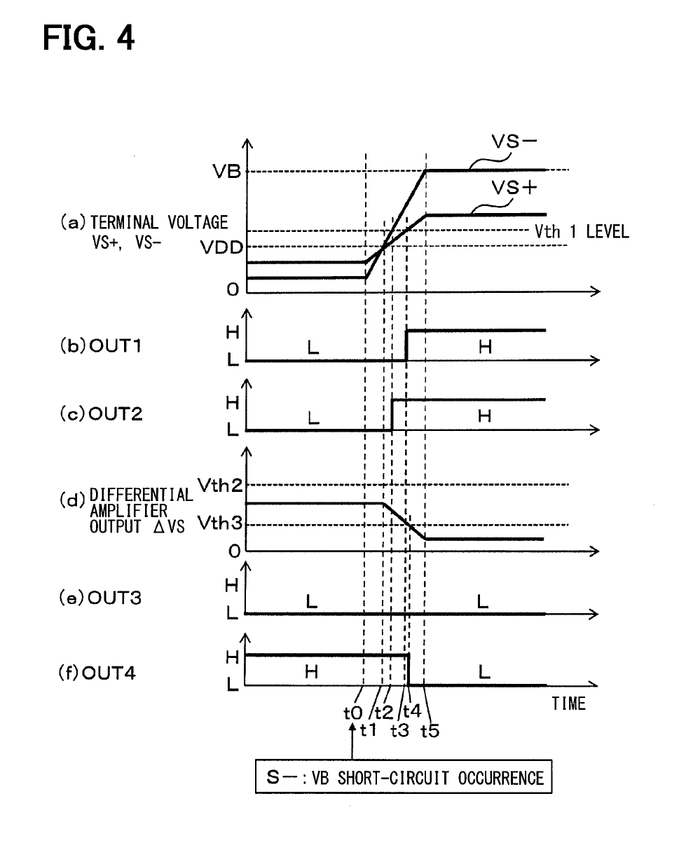

This state is different from the state shown in FIG. 1 in that the high-voltage power supply VB is short-circuited to the wiring line L2. FIG. 4 shows a transition of a change in the signal of each part corresponding to that case. It is assumed that the wiring line L2 is short-circuited to the high-voltage power supply VB at the time t0.

When the wiring line L2 is short-circuited to the high-voltage power supply VB at the time t0 from the normal state described above, the terminal voltages VS+ and VS− both rise as shown in (a) in FIG. 4, and in that case, the terminal voltage VS− reaches the level of the high-voltage power supply VB and the terminal voltage VS+ reaches a level lower than the high-voltage power supply VB. At that time, after the terminal voltage VS− first rises and exceeds the power supply voltage VDD at the time t1, the terminal voltage VS− exceeds the level of the threshold voltage Vth1 at the time t2. As a result, as shown in (c) in FIG. 4, the output signal OUT2 changes from the low level to the high level. At that time point, it can be seen that the wiring line L2 connected to the terminal S− is in contact with the high-voltage power supply VB, and thus has a high voltage. Therefore, a state indicated by “3” in FIG. 6 is obtained.

However, immediately after that situation, when the terminal voltage VS− rises and reaches the threshold voltage Vth1 level at the time t4, the output signal OUT1 changes from the low level to the high level as shown in (b) in FIG. 4. As a result, since both of the OUT1 and the OUT2 are at the high level in the same manner as described above, a state that one or both of the terminals S+ and S− are short-circuited to a high voltage exceeding the power supply voltage VDD can be determined, but which terminal is short-circuited cannot be specified.

On the other hand, the differential amplifier 45 outputs the result of calculating the differential voltage between the output voltages VSp and VSm of the overvoltage detection circuits 41 and 42 as the differential voltage ΔVS as shown in (d) in FIG. 4. Unlike the above-described case, since the output voltage VSm becomes higher than the output voltage VSp, when the differential voltage ΔVS drops to a negative side and falls below the threshold voltage Vth3, the comparator 54 outputs the low level output signal OUT4 at the time t4 as shown in (f) in FIG. 4.

Since the level of the differential voltage ΔVS before the time t0 has been already lower than the threshold voltage Vth2, the comparator 53 continues to output the low level output signal OUT3 even after the time t4. As a result, as a state indicated by “5” in FIG. 6, a state where the output signals OUT1 and OUT2 are “H” and the output signals OUT3 and 4 are “L” is obtained, and the S− terminal can be recognized as being short-circuited to the high-voltage power supply VB.

### (3) Case in Which Both Wiring Lines L1 and L2 are Short-Circuited to VB

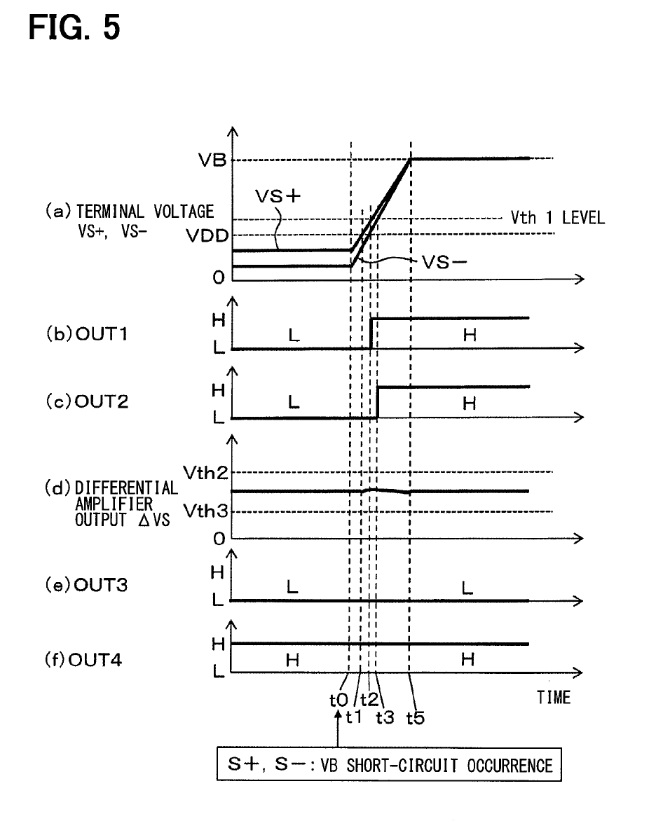

In this state, in addition to the state where the wiring line L1 is short-circuited to the high-voltage power supply VB, which is shown in FIG. 1, the wiring line L2 is also short-circuited to the high-voltage power supply VB. FIG. 5 shows a transition of a change in the signal of each part corresponding to that case. A case where the wiring lines L1 and L2 are simultaneously short-circuited to the high-voltage power supply VB at the time t0 will be described.

When the wiring lines L1 and L2 are short-circuited to the high-voltage power supply VB at the time t0 from the normal state described above, the terminal voltages VS+ and VS− both rise as shown in (a) in FIG. 5, and the terminal voltages VS+ and VS− reach the level of the high-voltage power supply VB. Thus, the difference between the terminal voltages VS+ and VS− decreases as the voltage rises, and finally, the terminal voltages VS+ and VS− become the same level.

Further, after the levels of the terminal voltages VS+ and VS− rise to exceed the power supply voltage VDD at the time t1, the terminal voltages VS+ and VS− exceed the level of the threshold voltage Vth1 at the times t2 and t3, respectively. This changes the output signal OUT1 and OUT2 from the low level to the high level, as shown in (b) and (c) in FIG. 5. As a result, the output signals OUT1 and OUT2 differ from the states of “2” and “3” in FIG. 6 described above, but become the same states as “4” and “5” in FIG. 6 after the lapse of time.

On the other hand, since the differential voltage between the output voltages VSp and VSm of the overvoltage detection circuits 41 and 42 decreases with the elapse of time from the time t0, the differential voltage ΔVS as the output from the differential amplifier 45 is substantially unchanged as shown in (d) in FIG. 5. As a result, as shown in (e) and (f) in FIG. 5, the output signals OUT3 and OUT4 of the comparators 53 and 54 are maintained at the low level and high level, respectively, without any change even after the time t0.

As a result, as an the state shown by “6” in FIG. 6, a state where the output signals OUT1 and OUT2 are “H” while the output signal OUT3 is “L” and the output signal OUT4 is “H” is obtained, and both of the S+ terminal and the terminal S− can be recognized as being short-circuited to the high-voltage power supply VB.

In the present embodiment described above, the overvoltage detection circuits 41 and 42 are provided, and the differential voltage ΔVS between the output voltages VSp and VSm of the overvoltage detection circuits 41 and 42 is calculated by the differential amplifier 45. As a result, the voltages of the terminal voltages VS+ and VS− of the terminals S+ and S− are converted into voltages in a range of the power supply voltage VDD by the overvoltage detection circuits 41 and 42, and the differential voltage ΔVS between the voltages is detected by the differential amplifier 45. Accordingly, whether one or both of the wiring lines L1 and L2 are short-circuited to the high-voltage power supply VB can be determined.

In addition, since the overvoltage detection circuits 41 and 42 are provided to convert a voltage equal to or higher than the power supply voltage into the voltages VSp and VSm based on the power supply voltage VDD, each circuit of the wiring line abnormality detection unit 40 can be configured by a circuit using the power supply voltage VDD as a power supply. Accordingly, there is no need to provide a circuit using the high-voltage power supply VB as a power supply, and each circuit of the wiring line abnormality detection unit 40 can be configured using components having a low breakdown voltage specification.

### Second Embodiment

FIG. 7 shows a second embodiment, and a portion different from the first embodiment will be described below. In the present embodiment, overvoltage detection circuits 41a and 42a shown in FIG. 7 are used instead of the overvoltage detection circuits 41 and 42. In contrast to the overvoltage detection circuits 41 and 42 shown in FIG. 2, the overvoltage detection circuits 41a and 42a shown in FIG. 7 have a configuration in which a capacitor 68 is provided instead of the resistor 67 of the output stage.

As a result, in the overvoltage detection circuits 41a and 42a, even when the terminal voltages VS+ and VS− become high voltages exceeding the power supply voltage VDD, the voltages exceeding the power supply voltage VDD can be converted into current values, converted into voltage signals VSp and VSm with reference to the power supply voltage VDD, and output. Therefore, the same operation and effect as those of the first embodiment can be obtained by the second embodiment.

### Third Embodiment

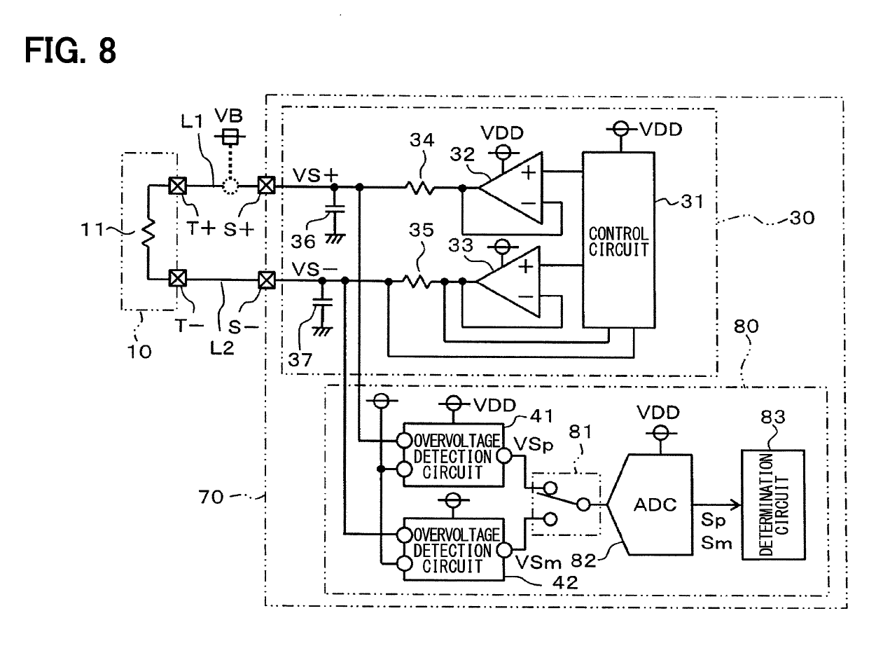

FIG. 8 shows a third embodiment, and a portion different from the first embodiment will be described below. In the present embodiment, a gas concentration detection device 70 is configured to include a wiring line abnormality detection unit 80 instead of the wiring line abnormality detection unit 40.

As shown in FIG. 8, the wiring line abnormality detection unit 80 has a configuration in which a changeover switch 81, an AD conversion circuit 82, and a determination circuit 83 are provided in a subsequent stage of overvoltage detection circuits 41 and 42. In the present embodiment, the overvoltage detection circuits 41 and 42 and the AD conversion circuit 82 function as a potential detection unit, and the determination circuit 83 functions as a potential difference detection circuit and a determination circuit.

Output signals VSp and VSm of the overvoltage detection circuits 41 and 42 are alternately input to the AD conversion circuit 82 by the changeover switch 81. The changeover switch 81 is operated by a control unit (not shown) at an appropriate timing. The AD conversion circuit 82 digitally converts output signals VSp and VSm input from the overvoltage detection circuit 41 or 42, and then outputs digital signals Sp and Sm to the determination circuit 83.

The determination circuits 83 compare the digital signals Sp and Sm with a threshold corresponding to the threshold voltages Vth1 and generate signals corresponding to the output signals OUT1 and OUT2 shown in the first embodiment. The determination circuit 83 calculates a difference ΔS between the digital signals Sp and Sm, compares the difference ΔS with thresholds corresponding to the threshold voltages Vth2 and Vth3, and generates signals corresponding to the output signals OUT3 and OUT4.

The determination circuit 83 may perform the same determination process as that of the first embodiment according to those signals to determine whether the wiring lines L1 and L2 are in a normal state or in a state short-circuited to the high-voltage power supply VB. In addition, the determination circuit 83 can specify that one or both of the wiring lines L1 and L2 are short-circuited to the high-voltage power supply VB based on the results of the output signals OUT1 to OUT4 in the same manner described above. Therefore, the same effects as those of the first embodiment can be obtained by the third embodiment.

### Fourth Embodiment

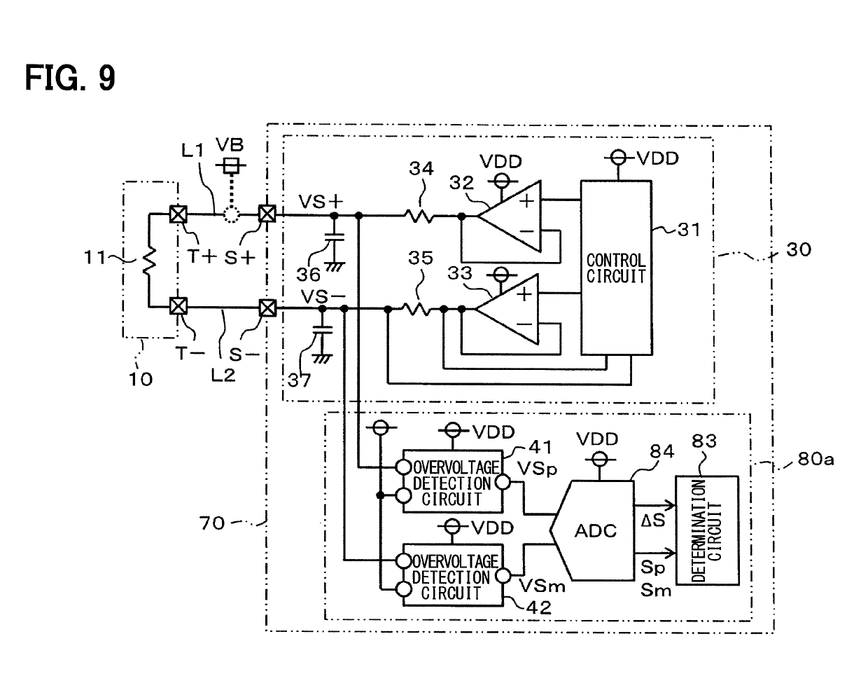

FIG. 9 shows a fourth embodiment, and a portion different from the third embodiment will be described below. In the present embodiment, a wiring line abnormality detection unit 80a is provided with a two-input AD conversion circuit 84 capable of directly calculating a difference instead of the AD conversion circuit 82. Accordingly, the changeover switch 81 can be omitted. In the present embodiment, the AD conversion circuit 84 functions as a potential difference detection circuit. Therefore, the same operation and effects as those of the third embodiment can be obtained by the fourth embodiment.

### Fifth Embodiment

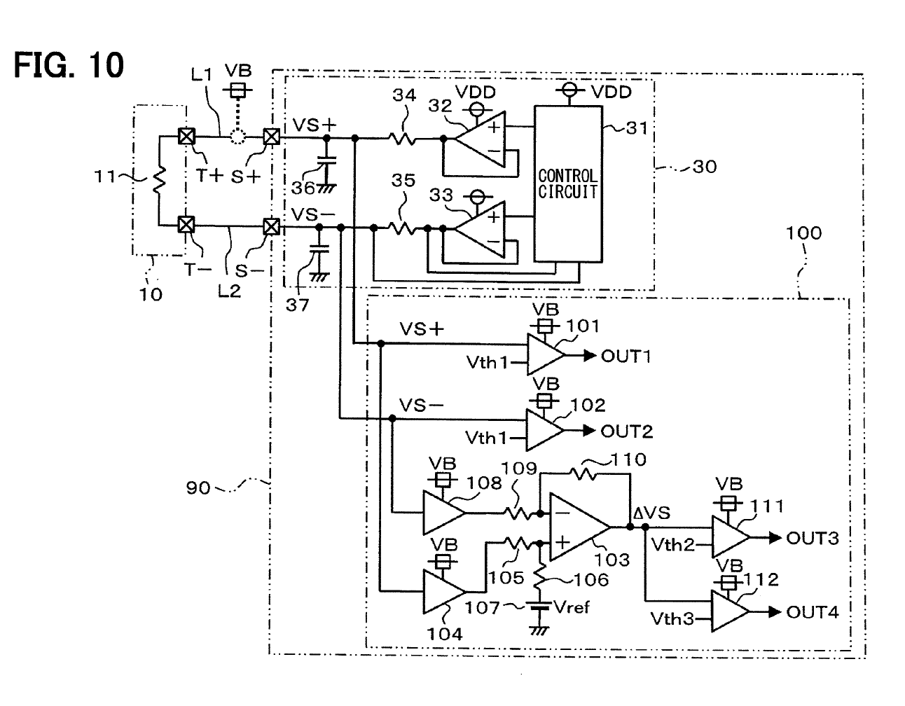

FIG. 10 shows a fifth embodiment, and a portion different from the first embodiment will be described below. In the present embodiment, a gas concentration detection device 90 is configured to include a wiring line abnormality detecting unit 100 instead of the wiring line abnormality detection unit 40.

As shown in FIG. 10, in the wiring line abnormality detection unit 100, an internal circuit is configured of a circuit in which a high-voltage power supply VB is used as a driving power supply as an overall. In other words, the wiring line abnormality detection unit 100 directly detects and determines the terminal voltages VS+ and VS− without being provided with the overvoltage detection circuits 41 and 42.

Comparators 101 and 102 compare terminal voltages VS+ and VS− of the terminals S+ and S−, respectively, with a threshold voltage Vth1, and output the result as output signals OUT1 and OUT2. The threshold voltage Vth1 is set so that levels of the voltages VS+ and VS− are set to a predetermined level equal to or higher than the power supply voltage VDD, and when a high voltage exceeding the power supply voltage VDD is applied to the wiring line L1 or L2, this fact is detected.

A differential amplifier 103, which is a high-voltage differential amplifier, has both functions of a potential detection unit and a potential difference detection circuit, and calculates a difference between the terminal voltages VS+ and VS− of the terminals S+ and S− to output a differential voltage ΔVS. A non-inverting input terminal of the differential amplifier 103 receives the terminal voltage VS+ from the terminal S+ through the buffer circuit 104 and the resistor 105. The non-inverting input terminal of the differential amplifier 103 is connected to the ground through a resistor 106 and a reference power supply 107. In the reference power supply 107, a voltage of ½ of the power supply voltage VDD is set as the reference voltage Vref. An inverting input terminal of the differential amplifier 103 receives the terminal voltage VS− from the terminal S− through the buffer circuit 108 and the resistor 109. A resistor 110 is connected between the inverting input terminal of the differential amplifier 103 and the output terminal.

The comparators 111 and 112 are provided so as to receive a differential voltage ΔVS, which is an output of the differential amplifier 103. In the comparators 111 and 112, the voltages to be compared are set to the threshold voltages Vth2 and Vth3, respectively. The threshold voltages Vth2 and Vth3 are to set determination levels for detecting a case where the wiring line L1 or L2 connected to the terminal S+ or S− is short-circuited with a power supply line having a voltage higher than the power supply voltage VDD. The comparators 111 and 112 compare the differential voltage ΔVS with the threshold voltage Vth2 or the threshold voltage Vth3, and output the result as output signals OUT3 and OUT4.

According to the configuration described above, since the wiring line abnormality detection unit 100 is configured by a circuit in which the internal circuit as an overall uses the high-voltage power supply VB as a driving power supply, unlike the first embodiment, with the configuration in which the overvoltage detection circuits 41 and 42 are not provided, the same operation and effects as those of the first embodiment can be obtained.

In the embodiments described above, the wiring line abnormality detection unit 100 is shown as a circuit configuration that is driven by the high-voltage power supply VB. However, the present disclosure is not limited to the above configuration, but a boosting circuit that generates a voltage equal to or greater than the high voltage power supply VB may be provided for driving.

### Sixth Embodiment

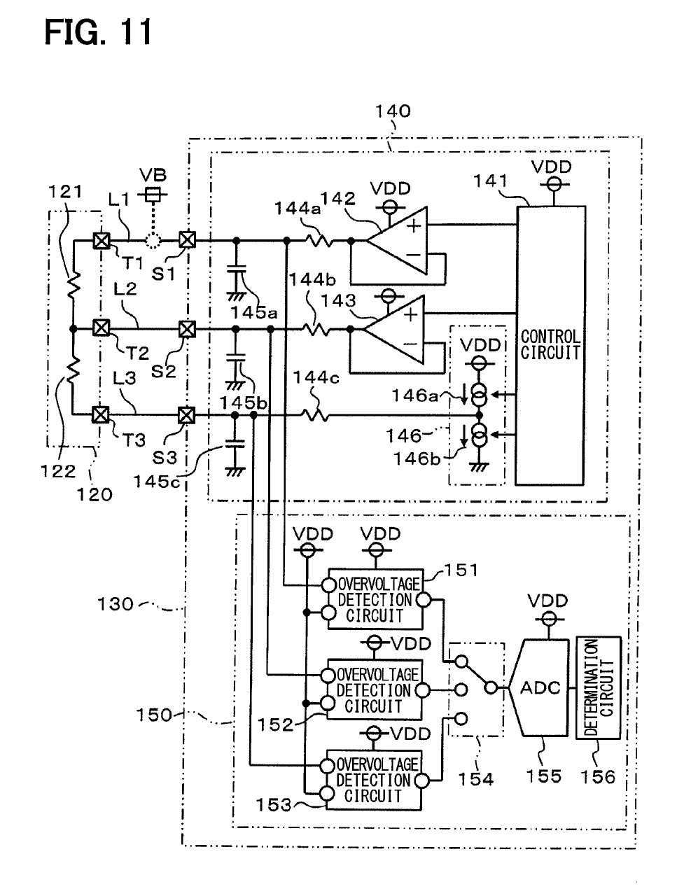

FIG. 11 shows a sixth embodiment, and a portion different from the third embodiment will be described below. The present embodiment shows an example in which a three-terminal gas concentration sensor 120 is used instead of the gas concentration sensor 10. In the present embodiment, the gas concentration detection device 130 includes a temperature detection unit 140 and a wiring line abnormality detection unit 150.

The gas concentration sensor 120 detects an oxygen concentration of an exhaust gas of an engine of a vehicle in the same manner as that of the gas concentration sensor 10 described above, and three terminals T1 to T3 are connected to terminals S1 to S3 of the gas concentration detection device 130 through wiring lines L1 to L3, respectively, in a configuration in which resistive portions 121 and 122 are connected in series to each other. The sensor 120 is heated by a heater circuit (not shown) when measuring the oxygen concentration.

The gas concentration detection unit 140 is mainly configured by a control circuit 141, and includes two amplifiers 142 and 143, three resistors 144a to 144c, three capacitors 145a to 145c, and a constant current drive circuit 146. The constant current drive circuit 146 includes two constant current circuits 146a and 146b connected between a DC power supply VDD and the ground. In the illustrated configuration, a wiring system for taking a signal for detecting the gas concentration into the control circuit 141 is omitted.

The wiring line abnormality detection unit 150 includes three overvoltage detection circuits 151 to 153 having the same configuration as that of the overvoltage detection circuit 41 described above. In addition, a changeover switch 154, an AD conversion circuit 155, and a determination circuit 156 are provided at a subsequent stage of the three overvoltage detection circuits 151 to 153. In the present embodiment, the overvoltage detection circuits 151 to 153 and the AD conversion circuit 155 function as a potential detection unit, and the determination circuit 156 functions as a potential difference detection circuit and a determination circuit.

The AD conversion circuit 155 takes in an output voltage from one of the overvoltage detection circuits 151 to 153 connected by the changeover switch 154, and converts the output voltage into a digital signal. The determination circuit 156 determines which of the wiring lines L1 to L3 connected to the terminals S1 to S3 is short-circuited to the high-voltage power supply VB based on the digital signal input from the AD conversion circuit 155.

In the configuration describe above, the detailed detection operation will not be described, but in the wiring line abnormality detection unit 150, the voltage signals are taken in from the two wiring lines in three combinations for the wiring lines L1 to L3, the differential voltage ΔVS between the wiring lines is calculated, and the wiring line short-circuited to the high-voltage power supply VB can be specified in the same manner as that in the third embodiment.

Therefore, according to the sixth embodiment described above, the same effects as those of the third embodiment can be obtained also in the gas concentration detection device 130 having the configuration using the three-terminal gas concentration sensor 120.

In the embodiments described above, the case where the three-terminal gas concentration sensor 120 is used has been described, but the present disclosure can also be applied to a gas concentration detection device targeting four or more terminals of the gas concentration sensor. In addition, although the above embodiment has been described as being applied to the third embodiment, the above embodiment can also be applied to the configuration of the first, second, fourth or fifth embodiment.

### Other Embodiments

It is to be noted that the present disclosure is not limited to the above-described embodiments, and can be applied to various embodiments without departing from the spirit thereof, and can be modified or expanded, for example, as follows.

In each of the above embodiments, the case where the gas concentration sensor is used as the sensor has been described, but the present disclosure can also be applied to a sensor signal detection device using another sensor. In the configuration in which the digital signal is converted using the AD conversion circuits 82, 84, and 155, the determination can be made by a logic circuit, or a determination process can be performed by software using a microcomputer or the like.

Although the disclosure has been described in accordance with the embodiments, it is understood that the present disclosure is not limited to such embodiment or structures. The present disclosure encompasses various modifications and variations within the scope of equivalents. In addition, various combinations and configurations, as well as other combinations and configurations that include only one element, more, or less, are within the scope and spirit of the present disclosure.

1. A wiring line abnormality detecting device configured to be provided in a sensor signal detection device that includes a detection unit for detecting a sensor signal through a plurality of wiring lines connected to a sensor, the wiring line abnormality detecting device comprising:
a potential detection unit that detects each of potentials of the plurality of wiring lines;
a potential difference detection circuit that detects a potential difference between the plurality of wiring lines according to each of the potentials of the plurality of wiring lines detected by the potential detection unit; and
a determination circuit that specifies a failure wiring line with a high-voltage power supply short circuit among the plurality of wiring lines according to the potential difference detected by the potential difference detection unit.

2. The wiring line abnormality detecting device according to claim 1, wherein
the potential detection unit includes a level shift circuit that shifts the potentials generated in the plurality of wiring lines to a low voltage level, and
the potential difference detection circuit includes a differential amplifier that calculates a difference between outputs of the level shift circuit.

3. The wiring line abnormality detecting device according to claim 1, wherein
the potential detection unit includes a level shift circuit that shifts the potentials generated in the plurality of wiring lines to a low voltage level, and an AD conversion circuit that converts the potentials shifted by the level shift circuit into digital values, and
the determination circuit also serves as the potential difference detection circuit.

4. The wiring line abnormality detecting device according to claim 1, wherein
the potential detection unit includes a level shift circuit that shifts the potentials generated in the plurality of wiring lines to a low voltage level, and
the potential difference detection circuit includes an AD conversion circuit that converts outputs of the level shift circuit into digital values and calculates the potential difference.

5. The wiring line abnormality detecting device according to claim 1, wherein
both the potential detection unit and the potential difference detection circuit are realized by a high-voltage differential amplifier that is driven by a high-voltage power supply equivalent to a power supply that generates the high-voltage power supply short circuit.

6. The wiring line abnormality detecting device according to claim 1, wherein
the sensor to which the plurality of wiring lines is connected is a gas concentration sensor.
